(19) United States
(12) Patent Application Publication
(10) Pub. No.: US 2015/0377949 A1
(43) Pub. Date: Dec. 31, 2015

(54) Utility Meter with Temperature Sensor

(71) Applicant: Landis+Gyr, Inc., Lafayette, IN (US)

(72) Inventor: Anibal Diego Ramirez, Indianapolis, IN (US)

(21) Appl. No.: 14/319,227

(22) Filed: Jun. 30, 2014

(51) Int. Cl. G01R 31/04; H02H 5/04

(52) U.S. Cl. CPC G01R 31/04; H02H 5/04

(57) ABSTRACT

A utility meter includes at least one primary coil, a temperature sensor, and a metrology circuit. The at least one primary coil is configured to be operably coupled to a meter socket to receive heat energy from the meter socket. The temperature sensor is operably coupled to the at least one primary coil and is configured to generate a sensor signal based on a temperature of the meter socket. The metrology circuit is operably coupled to the temperature sensor and is configured (i) to generate metering data based on a measurement of electricity consumption, and (ii) to generate a service signal in response to the sensor signal indicating that the temperature of the at least one primary coil is equal to or greater than a predetermined temperature threshold. The predetermined temperature threshold corresponds to a temperature indicative of the meter socket being due for maintenance.

### FIELD

This disclosure relates to the field of utility meters, and particularly, to an electricity meter having a temperature sensor.

### BACKGROUND

Utility meters are devices that, among other things, measure the consumption of a utility-generated commodity, such as electrical energy, gas, or water, by a residence, factory, commercial establishment or other such facility. Utility service providers utilize utility meters to track customer usage of the utility-generated commodities. Utility service provides track customer usage for many purposes, including billing and demand forecasting of the consumed commodity.

Electricity meters are a type of utility meter configured to measure the consumption of electrical energy by a facility. The typical electricity meter is connected to electrical power distribution lines with a mounting device. The mounting device includes connection jaws/sockets that become attached to blades extending from primary coils of the electricity meter when the electricity meter is connected to the mounting device. A benefit of the mounting device is that if the electricity meter requires maintenance or replacement, the electricity meter is easily separated from the mounting device to enable a technician to repair or to replace the meter.

In general, a mounting device simplifies the electrical connection of an electricity meter to the distribution lines; however, over time and with use the mounting device itself may require maintenance and/or replacement. For example, the connection sockets of some mounting devices may exhibit a gradual increase in resistance as the mounting device ages, thereby resulting in the electricity meter operating with a correspondingly decreasing level of efficiency. Problematically, it may be difficult for the utility provider and the customer to determine when the mounting device has aged/degraded in performance to a point that requires repair or replacement.

Thus, a continuing need exists to increase the performance of utility meters so that consumption data is accurately and reliably metered with minimal burden on the utility provider and the customer.

### SUMMARY

According to an exemplary embodiment of the disclosure, a utility meter includes at least one primary coil, a temperature sensor, and a metrology circuit. The at least one primary coil is configured to be operably coupled to a meter socket to receive heat energy from the meter socket. The temperature sensor is operably coupled to the at least one primary coil and is configured to generate a sensor signal based on a temperature of the meter socket. The metrology circuit is operably coupled to the temperature sensor and is configured (i) to generate metering data based on a measurement of electricity consumption, and (ii) to generate a service signal in response to the sensor signal indicating that the temperature of the at least one primary coil is equal to or greater than a predetermined temperature threshold. The predetermined temperature threshold corresponds to a temperature indicative of the meter socket being due for maintenance.

According to another exemplary embodiment of the disclosure, a method of operating a utility meter includes sensing a temperature of a primary coil including blades received by a meter socket with a temperature sensor operably coupled to the primary coil, the temperature of the primary coil corresponding to a temperature of the meter socket; generating a sensor signal with the temperature sensor that is based on the temperature of the meter socket; and generating an isolated signal based on the sensor signal with an electrical isolator operably coupled to the temperature sensor. The method further includes receiving the isolated signal with a metrology circuit operably coupled to the electrical isolator; and generating a service signal with the metrology circuit in response to the isolated signal indicating that the sensed temperature is equal to or greater than a predetermined temperature threshold, the predetermined temperature threshold corresponding to a temperature indicative of the meter socket being due for maintenance.

According to yet another exemplary embodiment of the disclosure, a method of operating a utility meter includes sensing a temperature of a primary coil including blades received by a meter socket with a temperature sensor operably coupled to the primary coil, the temperature of the primary coil corresponding to a temperature of the meter socket; forming a closed circuit through the primary coil with a disconnect unit of the utility meter when the sensed temperature is less than a first predetermined temperature threshold; forming a closed circuit through the primary coil with the disconnect unit and generating a first service signal with a metrology circuit operably coupled to the temperature sensor and the disconnect unit when the sensed temperature is equal to or greater than the first predetermined temperature threshold and less than a second predetermined temperature threshold that is greater than the first predetermined temperature threshold; and forming an open circuit through the primary coil with the disconnect unit and generating a second service signal with the metrology circuit when the sensed temperature is equal to or greater than the second predetermined temperature threshold.

### BRIEF DESCRIPTION OF THE FIGURES

The above-described features and advantages, as well as others, should become more readily apparent to those of ordinary skill in the art by reference to the following detailed description and the accompanying figures in which:

FIG. 1 is a block diagram illustrating an exemplary metering system, as disclosed herein, including a utility meter and a mounting device, the utility meter is configured to monitor a condition of electrical sockets of the mounting device with a temperature sensor;

FIG. 2 is a flowchart illustrating an exemplary method of operating the metering system of FIG. 1;

FIG. 3 is a schematic illustrating an exemplary temperature sensing and isolation circuit of the utility meter of FIG. 1;

FIG. 4 is a block diagram illustrating another exemplary metering system, as disclosed herein, including a utility meter and a mounting device, the utility meter is configured to monitor a condition of electrical sockets of the mounting device with a temperature switch;

FIG. 5 is a block diagram illustrating meter blades, a primary coil, a secondary current coil, and the temperature switch of the utility meter of FIG. 4, which is connected to the primary coil; and

FIG. 6 is a flowchart illustrating an exemplary method of operating the metering system of FIG. 4.

### DETAILED DESCRIPTION

For the purpose of promoting an understanding of the principles of the disclosure, reference will now be made to the embodiments illustrated in the drawings and described in the following written specification. It is understood that no limitation to the scope of the disclosure is thereby intended. It is further understood that this disclosure includes any alterations and modifications to the illustrated embodiments and includes further applications of the principles of the disclosure as would normally occur to one skilled in the art to which this disclosure pertains.

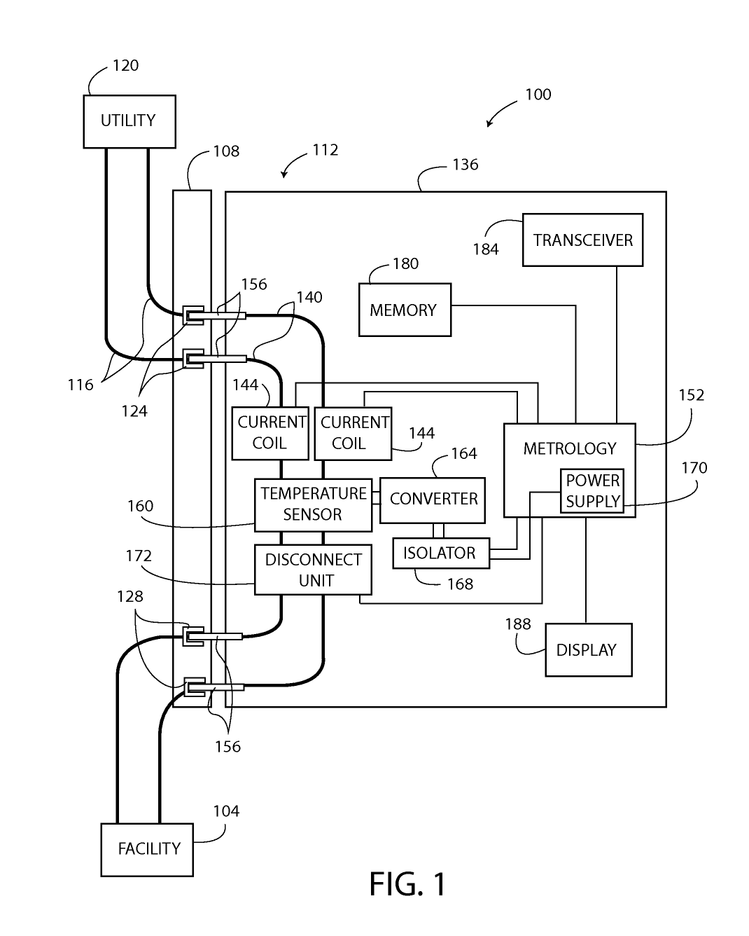

As shown in FIG. 1, a metering system 100 for a facility 104 includes a mounting device 108 and a utility meter 112 associated with electrical power distribution lines 116 that distribute electrical energy from a utility 120. In the exemplary arrangement of FIG. 1, the mounting device 108 includes two line-side sockets 124 electrically connected to the distribution lines 116, and two load-side sockets 128 electrically connected to the facility 104. The sockets 124, 128 are formed from metal and are configured to withstand high currents and voltages. In other embodiments, the mounting device 108 includes any suitable number of sockets 124, 128 formed from any suitable material.

The utility meter 112 includes a housing 136, at least one primary coil 140 (two shown in FIG. 1), at least one secondary coil 144 (two shown in FIG. 1), and a metrology circuit 152. The primary coils 140 are electrical conductors (e.g. copper conductors) that are located at least partially within the housing 136. The primary coils 140 each include two blades 156, which are configured to partially extend from the housing 136. The blades 156 are configured to provide a mechanically and electrically sound connection between the primary coils 140 and the sockets 124, 128. Specifically, the blades 156 are configured to be received by the sockets 124, 128 to operably connect the primary coils 140 to the sockets such that electrical power may be transferred through the utility meter 112. In other words, the electrical current drawn by the facility 104 passes through the primary coils 140 when the blades 156 are received by the sockets 124, 128. In addition, the primary coils 140 and the blades 156 may also mechanically support the meter 112 in a mounted position (as shown in FIG. 1) on the mounting device 108. Also, heat energy generated by sockets 124, 128 is transferred to the primary coils 140 through the blades 156, since the primary coils 140 and the blades 156 are typically formed from metal and are positioned in contact with the sockets 124, 128.

The secondary coils 144, which are also referred to herein as current coils, are disposed in a current sensing relationship with respect to the primary coils 140. The secondary coils 144 are configured to generate a scaled down version of the current passing through the primary coils 140. The scaled down current constitutes a current measurement signal. Accordingly, the primary coils 140 and the secondary coils 144 are configured as an electrical transformer. The secondary coils 144 are electrically connected to the metrology circuit 152 to couple the current measurement signal to the metrology circuit. In some embodiments, an electrical isolator device (not shown) is disposed between the secondary coils 144 and the metrology circuit 152 to provide galvanic isolation from the primary coils 140 to the metrology circuit 152.

The metrology circuit 152 is any suitable circuit(s) configured to generate metering data or consumption data by detecting, measuring, and determining one or more electricity and/or electrical energy consumption values based on electrical energy flowing from the line-side sockets 124 to the load-side sockets 128. Specifically, the metrology circuit 152 uses, among other signals, the isolated current measurement signal to determine the metering data. The utility 120 typically accesses the metering data for billing purposes as well as other purposes.

With reference still to FIG. 1, the utility meter 112 further includes a temperature sensor 160, a converter unit 164, and an electrical isolator 168. The temperature sensor 160 is operably coupled to at least one of the sockets 124, 128 and the metrology circuit 152. Specifically, the temperature sensor 160 is spaced apart from the sockets 124, 128 and is mechanically connected to at least one of the primary coils 140. Since the primary coils 140 and the sockets 124, 128 are configured to conduct heat energy, the primary coils have a temperature that is based on the temperature of the sockets. Thus, the temperature sensor 160 is configured to indirectly sense the temperature of the sockets 124,128 by sensing the temperature of the primary coils 140. In another embodiment, the temperature sensor 160 is mechanically connected to at least one of the meter blades 156 in a position that does not interfere with the sockets 124, 128 receiving the meter blades.

The temperature sensor 160 is configured to generate a temperature sensor signal that is based on the sensed temperature of the sockets 124, 128. The temperature sensor 160, in one embodiment, is configured to measure temperatures ranging from approximately 100° C. to approximately 300° C. The temperature sensor 160 may sense the temperature of the primary coils 140 and the sockets 124, 128 with a thermistor, a thermocouple, a diode, and/or any other suitable temperature sensing/detection device. Accordingly, the sensor signal, in one embodiment, is a variable electrical resistance level.

The converter unit 164 is operably coupled to the temperature sensor 160 to receive the sensor signal and to generate a converted signal based thereon. In particular, the converter unit 164 is configured to convert the sensor signal from a format generated by the temperature sensor 160 to a format that is desired/appropriate for the metrology circuit 152. In an exemplary embodiment, the converted signal is a pulse signal that defines a frequency based on the temperature of the sockets 124, 128. The frequency ranges from approximately 1 to 10 Hz, depending on the sensed temperature, and defines a duty cycle of substantially 50%. The converter unit 164 is configurable to represent the sensed temperature with any desired frequency range and with any desired duty cycle. In other embodiments, the converter unit 164 is configured to output a converted signal having any desired electrical characteristic for representing the sensed temperature, such as a variable amplitude, phase, and/or duty cycle, for example.

The electrical isolator 168 is electrically coupled to the converter 164, the temperature sensor 160, and to the metrology circuit 152, and is configured to provide galvanic isolation between the metrology circuit and the primary coils 140. The electrical isolator 168 is configured to protect the metrology circuit 152 from electrical variations that may occur in the distribution lines 116, the primary coils 140, the temperature sensor 160, and the converter unit 164. Additionally, the electrical isolator 168 is configured to generate an isolated signal that is based on the sensor signal and the converted signal. The isolated signal is provided to the metrology circuit 152. The electrical isolator 168 is supplied with electrical power from a power supply 170 of the metrology circuit 152. In another embodiment, the electrical isolator 168 is supplied with electrical power from any suitable power source. The electrical isolator 148 is provided as a transformer, an opto-isolator, or any other desired electrical isolator device.

With continued reference to FIG. 1, the utility meter 112 further includes a disconnect unit 172, a memory 180, a transceiver 184, and a display 188. The disconnect unit 172 is operably coupled to the primary coils 140 and the metrology circuit 152 and is configurable in a closed state (first state) and an open state (second state). In the closed state, a closed circuit is formed in the primary coils 140, which enables electrical power transfer from the utility 120 to the facility 104 (i.e. the load) through the distribution lines 116. In the open state, an open circuit is formed in the primary coils 140, which prevents electrical power transfer from the utility 120 to the facility 104 through the distribution lines 116. Specifically, in the open state electrical current is prevented from flowing from the line-side sockets 124 to the load-side sockets 128. The disconnect unit 172 includes a relay or any other suitable device that controllably disconnects and re-connects electrical power to the facility 104. As described below, the metrology circuit 152 is configured to control the state of the disconnect unit 172 based on the sensed temperature of the sockets 124.

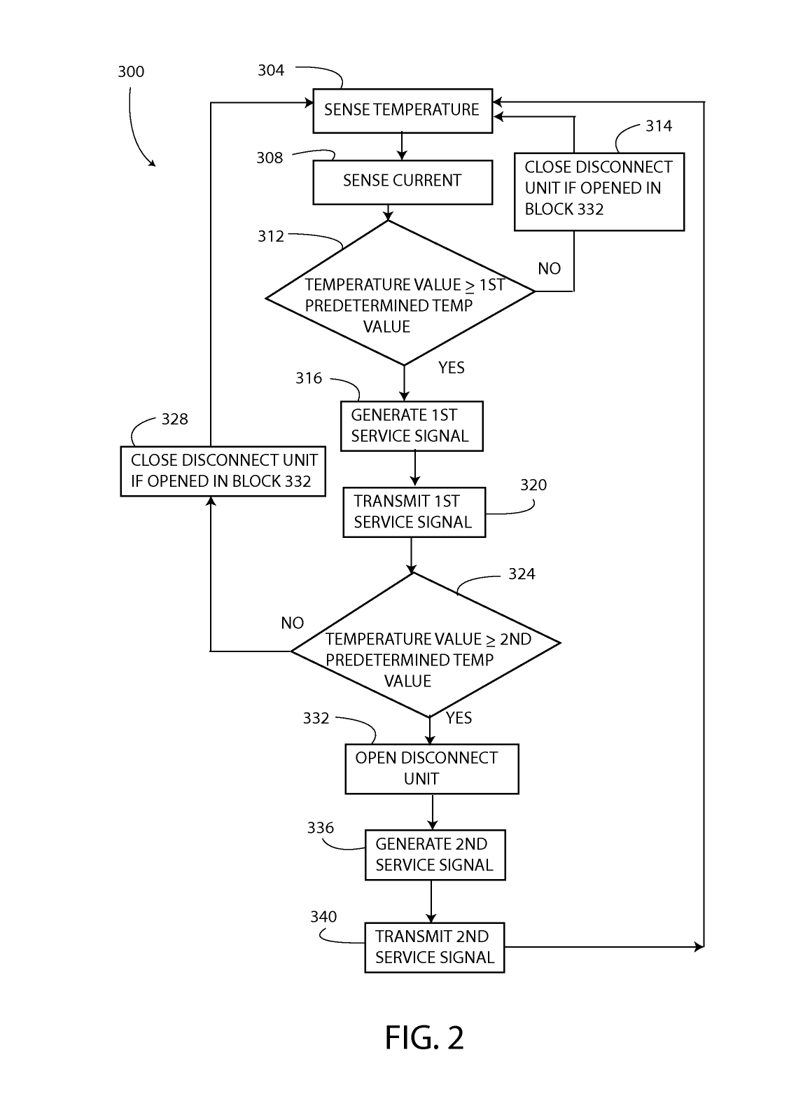

The memory 180 is operably coupled to the metrology circuit 152 and is configured to store metering data generated by the metrology circuit. Additionally, the memory 180 is configured to store look-up tables and program data for operating the temperature sensor 160 and the disconnect unit 172 according to the method 300 (FIG. 2) described below, as well as storing any other electronic data used or generated by the metrology circuit 152. The memory 180 is also referred to herein as a non-transitory machine readable storage medium.

The transceiver 184 is operably coupled to the metrology circuit 152 and is configured to send electric data to the utility 120 and/or to an external unit (not shown), and to receive electric data from the utility and/or the external unit. In one embodiment, the transceiver 184 is a radio frequency (“RF”) transceiver operable to send and to receive RF signals. In another embodiment, the transceiver 184 includes an automatic meter reading (AMR) communication module configured to transmit data to an AMR network and/or another suitable device. The transceiver 184 may also be configured for data transmission via the Internet over a wired or wireless connection. In other embodiments, the transceiver 184 is configured to communicate with an external device or the utility 120 by any of various means used in the art, such as power line communication, telephone line communication, or other means of communication.

The display 184 is operably coupled to the metrology circuit 152 and is configured to display data associated with the utility meter 112 in a visually comprehensible manner. For example, the display 184 may be configured to display consumption data, the state of the disconnect unit 172, and the sensed temperature of the sockets 124, 128, for example. The display 184 is provided as any desired display device, such as a liquid crystal display unit, for example.

In operation, the utility meter 112 is configured to monitor the condition of the sockets 124, 128 according to the method 300 illustrated in FIG. 2. As shown in block 304, the method 300 begins by sensing the temperature of the sockets 124, 128 with the temperature sensor 160. The temperature sensor 160 generates a sensor signal that is received by the converter unit 164, which converts the sensor signal to the converted signal. The isolator 168 receives the converted signal, provides galvanic isolation to the metrology circuit 152, and provides the isolated signal the metrology circuit.

As described above, the temperature sensor 160, indirectly determines the temperature of the sockets 124, 128 by directly sensing the temperature of the primary coils 140. The temperature of the primary coils 140 is typically the same as or just a few degrees different from the temperature of the sockets 124, 128, since the meter blades 156 and the primary coils are effective conductors of heat energy. Any difference in temperature between the sockets 124, 128 and the primary coils 140 is a known differential, for which the metrology circuit 152 is configured to account.

The sensed temperature is related to the condition/remaining service life of the sockets 124, 128. In particular, as the sockets 124, 128 age it is normal for the condition of the sockets to deteriorate and/or to become corroded, dirty, worn out, defective, or otherwise less efficient at conducting electricity. The decrease in efficiency of the sockets 124, 128 may result in an increased electrical contact resistance through the sockets, which causes an increased power dissipation at the sockets. The increased power dissipation causes the sockets 124, 128 to become hotter for a given amount of electrical current flowing therethrough, and may decrease the service life of the mounting device 108. The utility meter 112 is configured to monitor the temperature of the sockets 124, 128 and, in some embodiments, the current flowing therethrough in order to determine when the sockets should be serviced, replaced, and/or maintained.

As shown in block 308, next the metrology circuit 152 determines the current flowing the through the sockets 124, 128 and the primary coils 140 using the secondary coils 144. The magnitude of the current flowing through the sockets 124, 128 affects the temperature of the primary coils 140 and the sockets. In particular, as the current through the sockets 124, 128 and primary coils 140 is increased (i.e. corresponding to an increased power demand by the facility 104) the temperature of the sockets and the primary coils is also increased. Whereas, the temperature of the sockets 124, 128 and the primary coils 140 typically decreases in response to less current flowing through the sockets and the primary coils. Thus, an increase in temperature of the sockets 124, 128 as a result of an increased power demand by the facility 104 is a normal response and does not necessarily indicate that the sockets are functioning less efficiently.

Next, the metrology circuit 152 determines a first temperature threshold (also referred to herein as first predetermined value and a first predetermined temperature threshold) for the sockets 124, 128 based on the measured current. The first temperature threshold is an expected temperature of the sockets 124, 128 based on the measured current plus a first temperature delta value to account for any tolerable degradation of the sockets 124, 128. The first temperature threshold is selected to allow for an early detection of abnormal socket temperature 124, 128 before any damage to the utility meter 112 has occurred. An exemplary first temperature threshold is approximately 125° C. for a typical current through the primary coils 140. The metrology circuit 152, in one embodiment, determines the first temperature threshold using a look-up table stored in the memory 180. In other embodiments any desired method for determining the first temperature threshold may be used.

In block 312, the metrology circuit 152 determines if the sensed temperature value of the sockets 124, 128 is greater than or equal to the first temperature threshold value. If the sensed temperature is less than the first temperature threshold, then the metrology circuit 152 continues to monitor the temperature of the sockets 124, 128 without generating a call for service, since when the sensed temperature is below the first temperature threshold the sockets are operating normally and service is typically not desired. Also, as shown in block 314 when the sensed temperature is less than the first temperature threshold, the metrology circuit 152 maintains the disconnect unit 172 in the closed state to enable current flow through the primary coils 140.

In block 316, if the sensed temperature is greater than or equal to the first temperature threshold, the metrology circuit 152 generates a first service signal. When the temperature of the sockets 124, 128 is greater than the first temperature threshold, then the sockets have begun to operate less efficiently than desired and service/maintenance by the utility 120 may be desired.

In some embodiments, the metrology circuit 152 generates the first service signal as soon as the sensed temperature is equal to or greater than the first temperature threshold. In other embodiments, however, the metrology circuit 152 generates the first service signal after the sensed temperature is equal to or greater than the first temperature threshold for longer than a first predetermined time period. An exemplary first predetermined time is approximately one minute.

As shown in block 320, the metrology circuit 152 next causes the transceiver 184 to transmit the first service signal to an external unit (not shown) or to the utility 120. The transmitted signal includes electronic data indicating that the first service signal has been generated. Additionally, the transmitted signal may include electronic data identifying the type of utility meter 112, the location of the utility meter, the length of time that the first service signal has been generated, the sensed temperature, the current measurement signal, and any other data available to the metrology circuit 152. In addition or in alternative to transmitting the first service signal with the transceiver 184, in some embodiments the metrology circuit 152 causes the display 188 to indicate that the first service signal has been generated.

Next, the metrology circuit 152 determines a second temperature threshold (also referred to herein as a second predetermined value and a second predetermined temperature threshold), which is greater in magnitude than the first temperature threshold and is based on the current measurement signal. The second temperature threshold represents a temperature above which electrical current should be prevented from passing through the primary coils 140. Accordingly, the second temperature threshold corresponds to a temperature indicative of the sockets 124, 128 operating with an efficiency that is undesirable. Typically, the second temperature threshold corresponds to a temperature indicative of the sockets 124, 128 being ready for maintenance and/or servicing.

The metrology circuit 152, in one embodiment, determines the second temperature threshold using a look-up table stored in the memory 180. An exemplary second temperature threshold is approximately 150° C. for a typical current through the primary coils 140. In another embodiment, the metrology circuit 152 determines the second temperature threshold by adding a second temperature delta value to the expected temperature. The second temperature delta value is greater than the first temperature delta value. In other embodiments, any desired method for determining the second predetermined temperature may be used.

As shown in block 324, the metrology circuit 152 determines if the sensed temperature is greater than or equal to the second temperature threshold.

With reference to block 328, if the metrology circuit 152 determines that the sensed temperature is less than the second temperature threshold, then the metrology circuit configures the disconnect unit 172 in the closed state (if the disconnect unit was opened in response to the method 300) so that the facility 104 may continue to draw electrical power from the utility 120 over the distribution lines 116. Thus, when the sensed temperature is greater than or equal to the first temperature threshold and less than the second temperature threshold, the metrology circuit 152 configures the utility meter 112 for power consumption by the facility 104 and generates the first service signal to indicate that maintenance and/or servicing of the sockets 124, 128 may be required. Accordingly, the utility meter 112 provides an advance warning to the utility 120 that the sockets 124, 128 have begun to operate less efficiently than desired.

In block 332, if the metrology circuit 152 determines that the sensed temperature is greater than or equal to the second temperature threshold, then the metrology circuit configures the disconnect unit 172 in the open state that forms an open circuit through the primary coils 140 and prevents the facility 104 from drawing electrical power from the utility 120 through the utility meter 112. Thus, the metrology circuit 152 has determined that based on the sensed temperature and the measured current, the sockets 124, 128 are operating with an undesirable efficiency and that no further electrical power should be drawn by the facility 104 through the utility meter 112. When the disconnect unit 172 is in the open state and current is no longer flowing through the primary coils 140, the sockets 124, 128, the primary coils, and the blades 156 begin to decrease in temperature.

Also, as noted in block 336, after opening the disconnect unit 172, the metrology circuit 152 generates a second service signal. In some embodiments, the metrology circuit 152 generates the second service signal as soon as the sensed temperature is equal to or greater than the second temperature threshold. In other embodiments, however, the metrology circuit 152 generates the second service signal after the sensed temperature is equal to or greater than the second temperature threshold for longer than a second predetermined time period. An exemplary second predetermined time period is approximately one minute. The second predetermined time period may be the same as or different from the first predetermined time period.

Next, as shown in block 340, the metrology circuit 152 causes the transceiver 184 to transmit the second service signal to an external unit (not shown) or to the utility 120. The transmitted signal includes electronic data that indicates that the second service signal has been generated. Additionally, the transmitted signal may include electronic data that identifies the type of utility meter 112, the location of the utility meter, the length of time that the second service signal has been generated, the sensed temperature, the current measurement signal, and any other electric data available to the metrology circuit 152. In addition or in alternative to transmitting the second service signal with the transceiver 184, in some embodiments the metrology circuit 152 causes the display 188 to indicate that the second service signal has been generated.

After generating the second service signal (block 336) and transmitting/displaying the second service signal (block 340), the metrology circuit 152 continues to sense the temperature of the sockets 124, 128 (block 304). If the sensed temperature continues to equal or exceed the second temperature threshold (block 324), the disconnect unit 172 is maintained in the open state (block 332). If, however, the sensed temperature falls below the second temperature threshold, then the metrology circuit 152 re-configures the disconnect unit 172 in the closed state (block 328) to enable the facility 104 to draw electrical power from the utility 120 through the utility meter 112. It is noted that the utility meter 112 may include other functions that control the state of the disconnect unit 172. If one of these other functions has caused the disconnect unit 172 to be in the open state, then the method 300 does not cause the disconnect unit to be in the closed state. Thus, according to the method 300, the metrology circuit 152 causes the disconnect unit 172 to transition from the open state to the closed state only if the disconnect unit was opened in response to the sensed temperature being greater than or equal to the second temperature threshold.

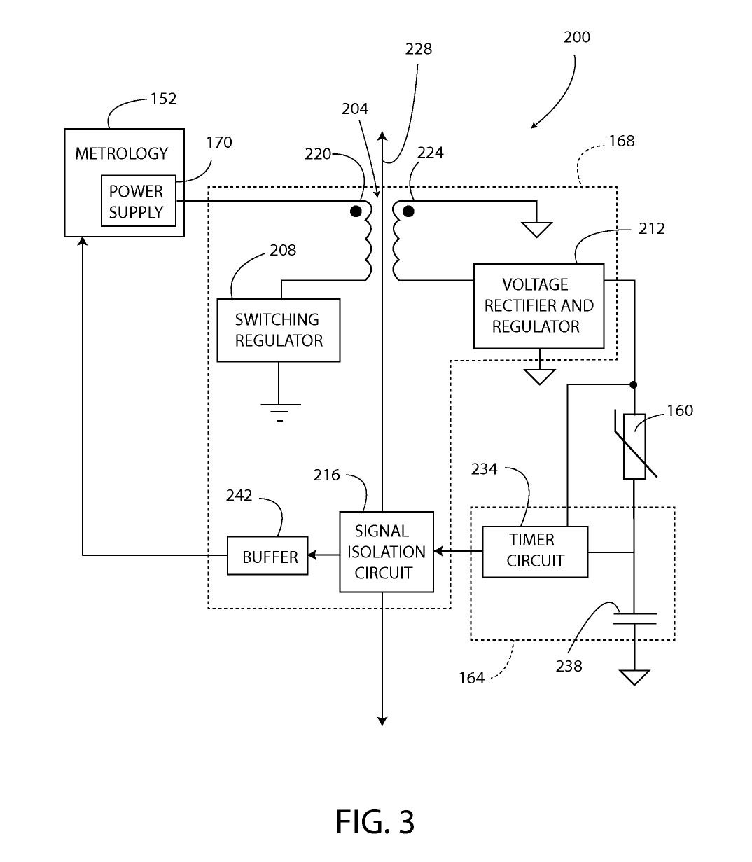

As shown in FIG. 3, an exemplary temperature sensing and isolation circuit 200 of the utility meter 112 includes the metrology circuit 152, the electrical isolator 168, the converter unit 164, and the temperature sensor 160. The electrical isolator 168 includes a transformer 204, a switching regulator 208, a voltage rectifier and regulator 212, and a signal isolation circuit 216. A first winding 220 of the transformer 204 is electrically connected to the power supply 170 and the switching regulator 208. A second winding 224 of the transformer 204 is connected to the voltage rectifier and regulator 212, the temperature sensor 160, and the converter unit 164. The transformer 204, in one embodiment, is provided as an L10-1322 isolated flyback transformer by BH Electronics, Inc. An reference isolation line 228 passes through the transformer 204 to emphasize that the circuit portions on the left of the isolation line are electrically isolated from the circuit portions on the right of the isolation line.

The switching regulator 208 is configured to generate a switched output signal that is electrically coupled to the first winding 220 of the transformer 204. The switching regulator is supplied with power from the power supply 170. In one embodiment, the switching regulator 208 is provided as an LT1425 isolated flyback switching regulator by Linear Technology.

The voltage rectifier and regulator 212 is configured to receive a switched output signal from the second winding 224 of the transformer 204. The voltage rectifier and regulator 212 is configured as a power supply that is isolated from the power supply 170 and the metrology circuit 152. Accordingly, the voltage rectifier and regulator 212 is configured to output a DC power signal for supplying power to the temperature sensor 160 and the converter unit 164. The voltage rectifier and regulator 212 may include an LM1117 linear regulator by Texas Instruments.

The converter unit 164 includes a timer circuit 234 and a capacitor 238 connected to the temperature sensor 160. The timer circuit 234 generates a pulsed output signal as a function of the resistance of the temperature sensor 160, which is shown as a thermistor. In one embodiment, the timer circuit 234 includes a 555 Timer provided as, for example, an LM555 from National Semiconductor.

The signal isolation circuit 216 is connected to the timer circuit 234 and the metrology circuit 152 through a signal buffer 242. The signal isolator circuit 216 is configured to provide galvanic isolation between the converter unit 164 and the metrology circuit 152, as shown by the position of the isolation line 228. In one embodiment, the signal isolator circuit 216 is provided as a digital isolator SI8621 from Silicon Labs. Accordingly, the signal isolator 216 is configured to modulate an RF signal based on the pulsed output signal, transmit the modulated signal through an internal isolation barrier (not shown), and then demodulate the transmitted signal. The demodulated output signal is passed through the buffer 242 and then is received by the metrology circuit 152 as the converted signal described above.

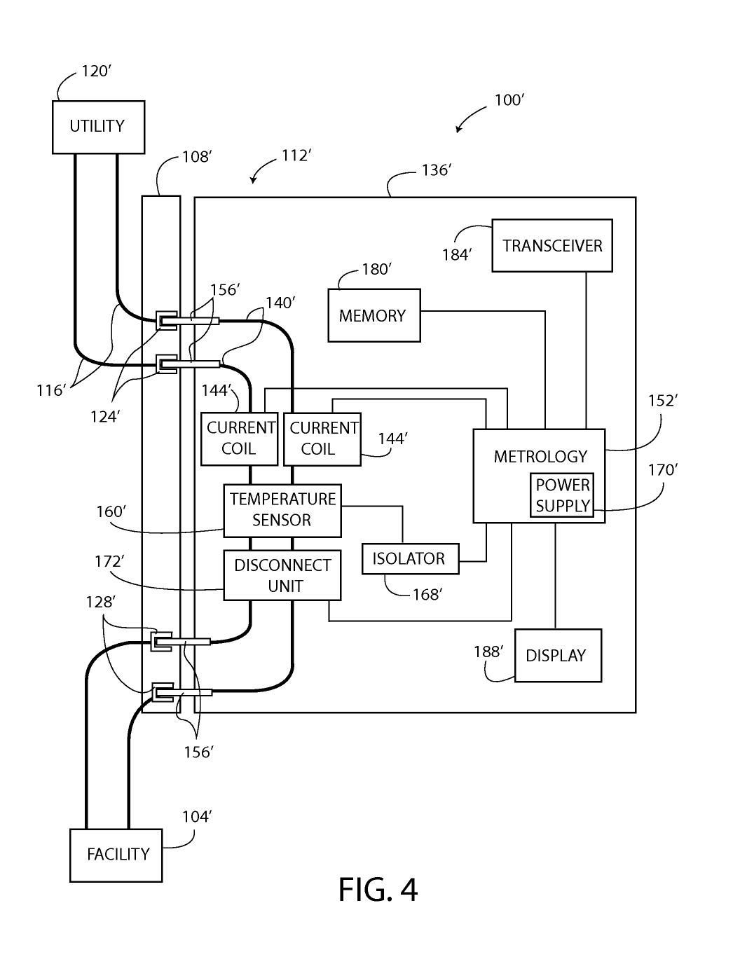

As shown in FIG. 4, another embodiment of a utility metering system 100′ includes a mounting device 108′ for connecting a utility meter 112′ to electrical power distribution lines 116′ configured to supply a facility 104′ with electrical power generated by a utility 120′. The mounting device 108′ includes sockets 124′, 128′ that electrically and mechanically connect to blade 156′ of primary coils 140′ extending from a housing 136′ of the utility meter 112′. The utility meter 112′ further includes secondary coils 144′ connected to a metrology circuit 152′ configured to determine consumption data of the facility 104′. A temperature sensor 160′ is connected to an electrical isolator 168′ and the metrology circuit 152′ for sensing the temperature of the sockets 124′. A disconnect unit 172′ is connected to the metrology circuit 152′ for forming either an open or a closed circuit through the primary coils 140′. A memory 180′, a transceiver 184′, and a display 188′ are also operably connected to the metrology circuit 152′.

The temperature sensor 160′ is connected to at least one of the primary coils 140′ and is configured to indirectly sense the temperature of the sockets 124′, as described above. The temperature sensor 160′ includes a temperature-controlled switch that defines a temperature threshold (also referred to herein as a trip-point temperature). Accordingly, when the sensed temperature is below the temperature threshold, the temperature sensor 160′ is in a first state (open state, for example), and when the sensed temperature is equal to or greater than the temperature threshold the temperature sensor 160′ is in a second state (closed state, for example). Therefore, a sensor signal generated by the temperature sensor 160′ is either a high potential signal representing the closed state or a low potential signal representing the open state. Typically, the temperature sensor 160′ is less expensive than the temperature sensor 160 (FIG. 1), thereby making the utility meter 100′ a cost effective device. An exemplary temperature sensor 160′ is the TSA01 from Intempco. The TSA01 is a bimetallic temperature switch with snap action or creep action outputs. The TSA01 has a tamper-proof preset temperature threshold ranging from 5° C. to 204° C.

The temperature threshold is selected to represent a temperature of the sockets 124′, 128′ above which the sockets are operating with an undesirably low efficiency. Thus, the temperature threshold allows for an early detection of an abnormal socket temperature 124′, 128′ before any damage to the utility meter 112′ has occurred. In an exemplary embodiment, the temperature threshold is approximately 150° C. The output of the temperature sensor 160′ is connected directly to the isolator 168′, such that a converter unit 164 (FIG. 1), is not included. Furthermore, it is noted that for added simplicity and cost reduction, the temperature threshold may be the same for all magnitudes of current through the meter blades 140′. Thus, in such an embodiment, the threshold temperature is fixed and is not based on the current measurement signal.

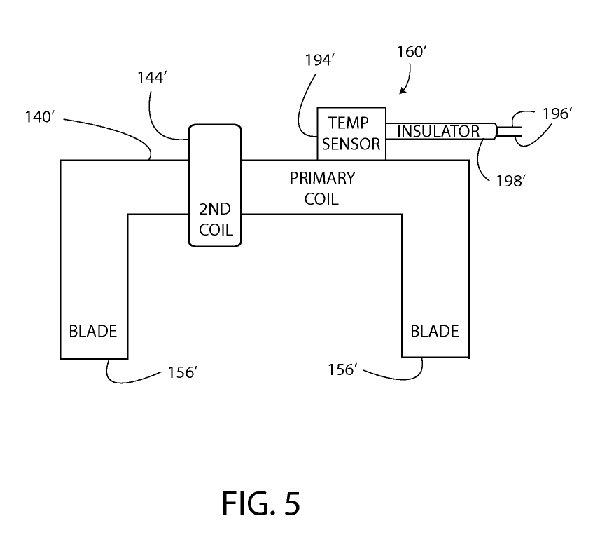

In FIG. 5, the temperature sensor 160′ is shown connected to the primary coil 140′. The temperature sensor 160′ includes a temperature sensitive portion 194′ and signal output wires 196′, which are encased by an electrically insulating material 198′. The insulating material 198′ prevents the signal output wires 196′ from making electrical contact with the primary coil 140′.

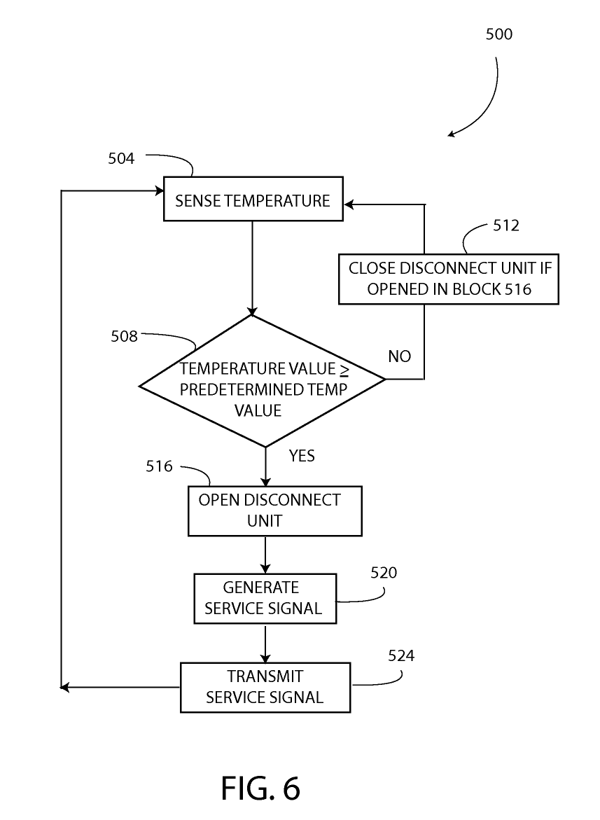

An exemplary method 500 of operating the utility meter 112′ is shown by the flowchart of FIG. 6. In block 504, the metrology circuit 152′ is configured to sense the temperature of the sockets 124′, 128′. In block 508, the metrology circuit 152′ determines if the sensor signal is at a low potential, indicating that the temperature of the sockets 124′, 128′ is below the temperature threshold (for example), or a high potential, indicating that the temperature of the sockets is equal to or greater than the temperature threshold (for example).

As shown in block 512, if the metrology circuit 152′ determines that the temperature of the sockets 124′, 128′ is less than the temperature threshold, then the metrology circuit configures the disconnect unit 172′ in the closed state, if the disconnect unit has been opened in the response to the method 500. In the closed state, the facility 104′ is able to draw electrical power from the utility 104′ through the utility meter 112′.

In block 516, if the metrology circuit 152′ has determined that the temperature of the sockets 124′, 128′ is greater than the temperature threshold, then the metrology circuit configures the disconnect unit 172′ in the open state, which forms an open circuit through the primary coils 140′, that prevents current from flowing through the meter blades 156′, the primary coils 140′, and the sockets 124′, 128′ and allows the sockets 124′, 128′ to cool.

Next, in blocks 520 and 524, the metrology circuit 152′ generates a service signal and then transmits the service signal to an external unit (not shown) or to the utility 120′ to alert the utility that the utility meter 112′ has been configured to halt the flow of current to the facility 104′.

When the temperature of the meter blades 140′ cools below the temperature threshold, the temperature sensor 160′ enters the open state. The transition of the temperature sensor 160′ from the closed state to the open state is sensed by the metrology circuit 152′ and as shown in block 512, the metrology circuit re-configures the disconnect unit 172′ in the closed state to enable current to flow through the meter blades 140′ to the facility 104′. Of course, the method 500 does not cause the disconnect unit 172′ to enter the closed state if another process has determined that the disconnection unit should remain in the open state.

The utility meter 112′ in other embodiments may include more than one temperature sensor 160′. In such an embodiment each temperature sensor 160′ defines a different temperature threshold. For example, the utility meter 112′ may include two of the temperature sensors 160′ connected to at least one of the primary coils 140′ and to the metrology circuit 152′. A first temperature sensor 160′ defines a first temperature threshold, and a second temperature sensor defines a second temperature threshold that is greater than the first temperature threshold. The metrology circuit 152′ is configured to generate a first service signal in response to the temperature sensed by the first temperature sensor 160′ being greater than the first temperature threshold, and to generate a second service signal in response to the temperature sensed by the second temperature sensor being greater than the second temperature threshold.

While the disclosure has been illustrated and described in detail in the drawings and foregoing description, the same should be considered as illustrative and not restrictive in character. It is understood that only the preferred embodiments have been presented and that all changes, modifications and further applications that come within the spirit of the disclosure are desired to be protected.

What is claimed is:

1. A utility meter comprising:
at least one primary coil configured to be operably coupled to a meter socket to receive heat energy from the meter socket;
a temperature sensor operably coupled to the at least one primary coil and configured to generate a sensor signal based on a temperature of the meter socket; and
a metrology circuit operably coupled to the temperature sensor and configured (i) to generate metering data based on a measurement of electricity consumption, and (ii) to generate a service signal in response to the sensor signal indicating that the temperature of the at least one primary coil is equal to or greater than a predetermined temperature threshold, the predetermined temperature threshold corresponding to a temperature indicative of the meter socket being due for maintenance.

2. The utility meter of claim 1, further comprising:
an electrical isolator operably coupled to the temperature sensor and the metrology circuit and configured (i) to generate an isolated signal based on the sensor signal, and (ii) to electrically isolate the metrology circuit from the at least one primary coil,
wherein the metrology circuit is further configured to receive the isolated signal.

3. The utility meter of claim 1, further comprising:
a converter unit operably coupled to the temperature sensor and the metrology circuit and configured to generate a converted signal based on the sensor signal,
the converted signal defining a frequency based on the temperature of the meter socket,
wherein the metrology circuit is configured to receive the converted signal.

4. The utility meter of claim 3, wherein:
the frequency of the converted signal ranges from 1 Hz to 10 Hz based on the temperature of the meter socket, and
the converted signal defines a substantially 50% duty cycle.

5. The utility meter of claim 1, further comprising:
a secondary coil operably coupled to the at least one primary coil and the metrology circuit, and configured to generate a current measurement signal based on a current flowing through the at least one primary coil,
wherein the metrology circuit is further configured to determine the predetermined temperature threshold and the measurement of electricity consumption based on the current measurement signal.

6. The utility meter of claim 1, wherein:
the temperature sensor includes a switch having a first state and a second state,
the switch is configured to be in the first state when the temperature of the meter socket is less than the predetermined temperature threshold,
the switch is configured to be in the second state when the temperature of the meter socket is equal to or greater than the predetermined temperature threshold, and
the metrology circuit is further configured to generate the service signal when the switch is in the second state.

7. The utility meter of claim 1, further comprising:
a transceiver operably coupled to the metrology circuit,
wherein the metrology circuit is configured to cause the transceiver to transmit the service signal to a utility.

8. The utility meter of claim 1, further comprising:
a disconnect unit operably coupled to the at least one primary coil and the metrology circuit, the disconnect unit configurable in (i) an open state in which an open circuit is formed in the at least one primary coil, and (ii) a closed state in which a closed circuit is formed in the at least one primary coil,
wherein the metrology circuit is further configured (i) to cause the disconnect unit to be in the closed state when the temperature of the meter socket is less than the predetermined temperature threshold, and (ii) to cause the disconnect unit to be in the open state when the temperature of the meter socket is greater than or equal to the predetermined temperature threshold.

9. A method of operating a utility meter comprising:
sensing a temperature of a primary coil including blades received by a meter socket with a temperature sensor operably coupled to the primary coil, the temperature of the primary coil corresponding to a temperature of the meter socket;
generating a sensor signal with the temperature sensor that is based on the temperature of the meter socket;
generating an isolated signal based on the sensor signal with an electrical isolator operably coupled to the temperature sensor;
receiving the isolated signal with a metrology circuit operably coupled to the electrical isolator; and
generating a service signal with the metrology circuit in response to the isolated signal indicating that the sensed temperature is equal to or greater than a predetermined temperature threshold, the predetermined temperature threshold corresponding to a temperature indicative of the meter socket being due for maintenance.

10. The method of claim 9, further comprising:
generating a converted signal based on the sensor signal with a converter unit operably coupled to the temperature sensor and the electrical isolator, the converted signal defining a frequency based on the temperature of the meter socket; and
isolating the converted signal with the electrical isolator to generate the isolated signal.

11. The method of claim 9, further comprising:
sensing a current flowing through the primary coil with a secondary coil operably coupled to the primary coil and the metrology circuit;
determining an expected temperature value based on the sensed current; and
determining the predetermined temperature threshold by adding a delta value to the expected temperature value.

12. The method of claim 9, further comprising:
forming a closed circuit in the primary coil with a disconnect unit of the utility meter in response to the sensed temperature being less than the predetermined temperature threshold, the disconnect unit operably coupled to the primary coil and the metrology circuit; and
forming an open circuit in the primary coil with the disconnect unit in response to generating the service signal.

13. The method of claim 9, wherein the metrology circuit is configured to generate the service signal in response to the sensed temperature being equal to or greater than the predetermined temperature threshold for longer than a predetermined time period.

14. The method of claim 9, further comprising:
transmitting the service signal to a utility with a transceiver operably coupled to the metrology circuit, in response to generating the service signal.

15. The method of claim 9, further comprising:
displaying data associated with the service signal on a display of the utility meter that is operably coupled to the metrology circuit, in response to generating the service signal.

16. The method of claim 9, wherein the service signal is a first service signal and the predetermined temperature threshold is a first predetermined temperature threshold, the method further comprising:
generating a second service signal with the metrology circuit in response to the isolated signal indicating that the sensed temperature is equal to or greater than a second predetermined temperature threshold that is greater than the first predetermined temperature threshold,
wherein the second predetermined temperature threshold corresponds to a sensed temperature indicative of the meter socket being due for additional maintenance.

17. A method of operating a utility meter comprising:
sensing a temperature of a primary coil including blades received by a meter socket with a temperature sensor operably coupled to the primary coil, the temperature of the primary coil corresponding to a temperature of the meter socket;
forming a closed circuit through the primary coil with a disconnect unit of the utility meter when the sensed temperature is less than a first predetermined temperature threshold;
forming a closed circuit through the primary coil with the disconnect unit and generating a first service signal with a metrology circuit operably coupled to the temperature sensor and the disconnect unit when the sensed temperature is equal to or greater than the first predetermined temperature threshold and less than a second predetermined temperature threshold that is greater than the first predetermined temperature threshold; and
forming an open circuit through the primary coil with the disconnect unit and generating a second service signal with the metrology circuit when the sensed temperature is equal to or greater than the second predetermined temperature threshold.

18. The method of claim 17, further comprising:
transmitting the first service signal to a utility with a transceiver operably coupled to the metrology circuit, in response to the generating the first service signal; and
transmitting the second service signal to the utility with the transceiver, in response to generating the second service signal.

19. The method of claim 17, further comprising:
forming a closed circuit through the primary coil with the disconnect unit after generating the second service signal in response to the sensed temperature being less than the second predetermined temperature threshold.

20. The method of claim 17, further comprising:
generating the first service signal when the sensed temperature is equal to or greater than the first predetermined temperature threshold and less than the second predetermined temperature threshold for longer than a predetermined time period; and
generating the second service signal when the sensed temperature is equal to or greater than the second predetermined temperature threshold for longer than the predetermined time period.
